(19) United States
(12) Patent Application Publication
(10) Pub. No.: US 2008/0153315 A1
(43) Pub. Date: Jun. 26, 2008

(54) Wafer processing method

(75) Inventor: Hiroshi Morikazu, Ota-ku (JP)

Correspondence Address: GREER, BURNS & CRAIN, 300 S WACKER DR, 25TH FLOOR, CHICAGO, IL, 60606, US

(73) Assignee: Disco Corporation, Tokyo (JP)

(21) Appl. No.: 12/002,036

(22) Filed: Dec. 14, 2007

(30) Foreign Application Priority Data
Dec. 26, 2006 (JP) 2006-349914

(51) Int. Cl. H01L 21/00

(52) U.S. Cl. 438/795; 257/E21.001

(57) ABSTRACT

In a wafer processing method of radiating a pulsed-laser beam to a wafer from a back surface of a silicon substrate to form via holes reaching respective bonding pads, a plurality of devices being formed on a surface of the silicon substrate, the bonding pads being formed on each of the devices, a thickness of said bonding pad is set as being equal to or larger than 5 μm, a wavelength of the pulsed-laser beam is set to 355 nm, and an energy density per one pulse of the pulsed-laser beam is set in a range of 20 to 35 J/cm².

### BACKGROUND OF THE INVENTION

1. Field of the Invention

The present invention relates to a wafer processing method of radiating a pulsed-laser beam to a wafer in which a plurality of devices are formed on a surface of a substrate, and bonding pads are formed on each of the devices from a back surface side of the substrate, thereby forming via holes reaching respective bonding pads.

2. Description of the Related Art

In semiconductor device manufacturing processes, a semiconductor wafer having an approximate disc-like shape is partitioned into a plurality of regions by intended lines of division called streets which are disposed in matrix on a surface of the semiconductor wafer. In addition, devices such as ICs or LSIs are formed in the regions of the semiconductor wafer obtained through the partition. Also, the semiconductor wafer is cut off into chips which have the regions having the devices formed therein, respectively. In such a way, individual semiconductor chips are manufactured.

In order to realize miniaturization and a high performance, a module structure in which a plurality of semiconductor chips are laminated, and bonding pads of the semiconductor chips thus laminated are connected is put into practical use. In this module structure, pluralities of devices are formed on a surface of a substrate constituting a semiconductor wafer, and the bonding pads are formed on each of the devices. In addition, via holes are defined in positions where the bonding pads are formed, respectively, from a back surface side of the substrate by drilling the substrate, and a conductive material such as aluminum or copper intended to be connected to corresponding one of the bonding pads is filled in each of the via holes (for example, referred to in Japanese Patent Laid-open No. 2003-163323).

The above-mentioned via hole to be defined in the semiconductor wafer is generally formed by drilling the substrate. However, the via hole formed in the semiconductor wafer has a small diameter in the range of 10 to 300 μm, and thus the process for drilling the substrate using a drill to define therein the via hole can not be necessarily satisfied in terms of productivity. Moreover, a thickness of the above bonding pad is about 1 μm, which results in that for the purpose of forming the via hole only in the substrate made of silicon or the like forming the semiconductor wafer without damaging the bonding pad, the drill needs to be very precisely controlled.

In order to solve the problems described above, the applicant of this patent application proposed a method of drilling a wafer in Japanese Patent Application No. 2005-249643. The contents of Japanese Patent Application No. 2005-249643 are as follows. That is to say, a pulsed-laser beam is radiated to a wafer in which a plurality of devices are formed on a surface of a substrate, and bonding pads are formed on each of the devices from a back surface side of the substrate, thereby efficiently forming the via holes reaching the respective bonding pads. The pulsed-laser beam used in the wafer drilling method described above is preferably set to have an energy density with which the substrate of the wafer is efficiently ablation-processed, but none of the bonding pads is ablation-processed. In addition, for the purpose of forming the via holes reaching the respective bonding pads in the substrate of the wafer, it is necessary to radiate the pulsed-laser beam to the substrate of the wafer from the back surface side of the substrate by 40 to 80 pulses. When the via holes reaching the respective bonding pads are formed in the substrate of the wafer by radiating the pulsed-laser beam to the substrate of the wafer by 40 to 80 pulses in such a manner, there is caused a problem that the heat generated by radiation of the pulsed-laser beam is accumulated, so that when each of the bonding pads has a small thickness of about 1 μm, it may be molten to make a hole in its position.

### SUMMARY OF THE INVENTION

It is therefore an object of the present invention to provide a wafer processing method with which a via hole reaching a bonding pad can be formed in a substrate of a wafer without making a hole in the bonding pad.

In accordance with an aspect of the present invention, there is provided a wafer processing method of forming a via hole in a wafer having a surface on which a plurality of devices having bonding pads are formed, the wafer processing method including the step of: forming the via hole reaching the bonding pad by radiating a pulsed-laser beam to the wafer from a back surface side of the wafer; in which a thickness of the bonding pad is set as being equal to or larger than 5 μm, a wavelength of the pulsed-laser beam is set to 355 nm, and an energy density per one pulse of the pulsed-laser beam is set in a range of 20 to 35 J/cm².

Preferably, the bonding pad is made of any one of gold, nickel, titanium, tantalum, cobalt, tungsten, and copper.

According to the wafer processing method of the present invention, the energy density per one pulse of the pulsed-laser beam is set in the range of 20 to 35 J/cm² with which the silicon substrate is ablation-processed, but none of the bonding pads is ablation-processed, and the thickness of the bonding pad is set as being equal to or larger than 5 μm. As a result, the via hole reaching the bonding pad can be formed in the silicon substrate without making a hole in the bonding pad.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a semiconductor wafer as a wafer which is processed by utilizing a wafer processing method according to an embodiment of the present invention;

FIG. 2 is a perspective view of a main portion of laser beam processing apparatus for implementing the wafer processing method according to the embodiment of the present invention;

FIG. 3 is a schematic block diagram showing a construction of a laser beam radiating means with which the laser beam processing apparatus shown in FIG. 2 is equipped;

FIG. 4 is an exemplary view explaining a via hole forming process in the wafer processing method according to the embodiment of the present invention; and

FIG. 5 is a partially enlarged cross sectional view of a semiconductor wafer in which via holes are formed by implementing the via hole forming process in the wafer processing method according to the embodiment of the present invention.

### DETAILED DESCRIPTION OF THE PREFERRED EMBODIMENTS

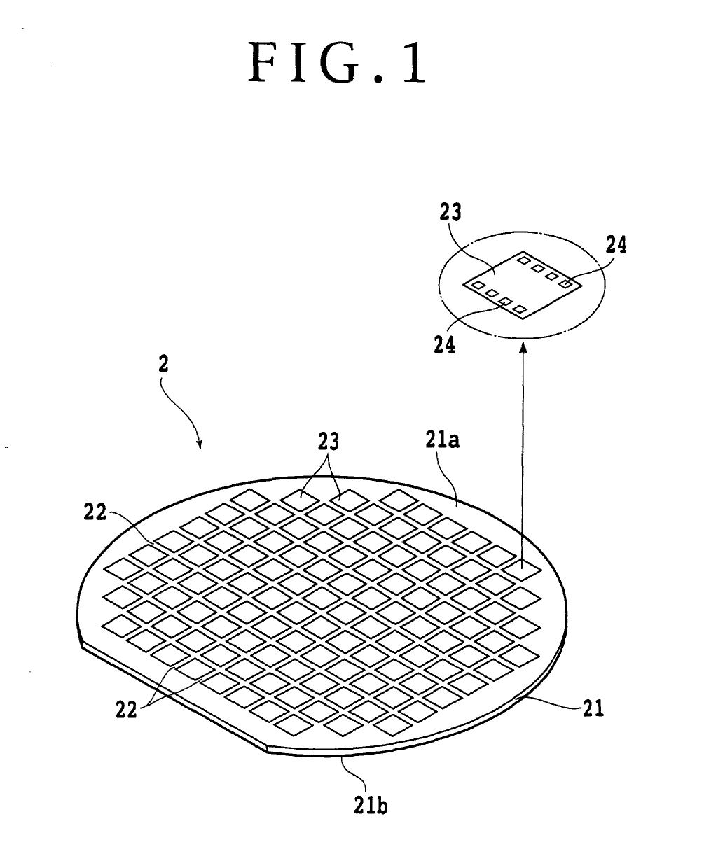

Hereinafter, a wafer processing method according to an embodiment of the present invention will be described in detail with reference to the accompanying drawings. FIG. 1 shows a perspective view of a semiconductor wafer 2 which is processed by utilizing the wafer processing method according to the embodiment of the present invention. The semiconductor wafer 2 shown in FIG. 1 is a partitioned into a plurality of regions by a plurality of streets 22 which are disposed in lattice on a surface 21a of a substrate 21 made of silicon having a thickness of 100 μm for example. Also, devices 23 such as ICs or LSIs are formed in the regions obtained through the partition of the semiconductor wafer 2, respectively. All the devices 23 have the same structure. In addition, a plurality of bonding pads 24 are formed on each of surfaces of the devices 23.

A material for the bonding pad 24 is preferably selected from the group consisting of gold (Au: 1,769° C. (melting point)), nickel (Ni: 1,453° C. (melting point)), titanium (Ti: 1,660° C. (melting point)), tantalum (Ta: 2,996° C. (melting point)), cobalt (Co: 1,495° C. (melting point)), tungsten (W: 3,410° C. (melting point)), and copper (Cu: 1,083° C. (melting point)) as metals each having a high melting point and relatively low thermal absorptivity. In addition, a thickness of the bonding pad 24 is set as being equal to or larger than 5 μm. It is noted that although the bonding pad is generally made of aluminum (Al: 660° C. (melting point)) having a thickness of about 1 μm, it may also be formed to have a thickness of 5 μm or more by laminating any one of the metals described above each having the high melting point and the relatively low thermal absorptivity by performing vacuum evaporation or the like.

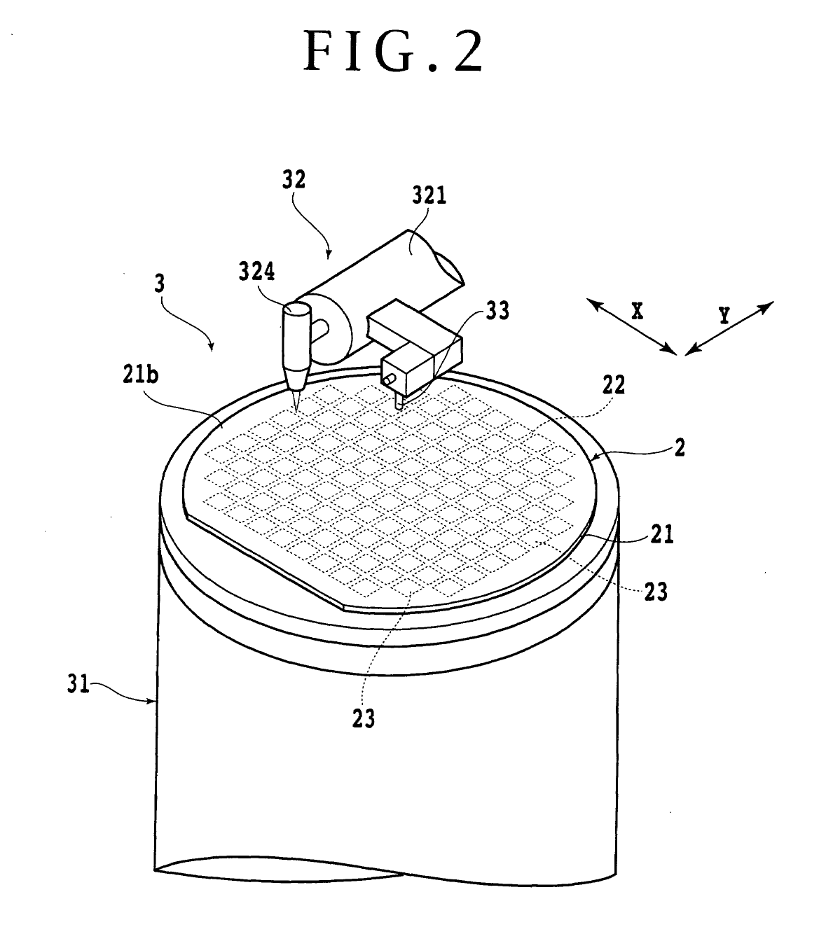

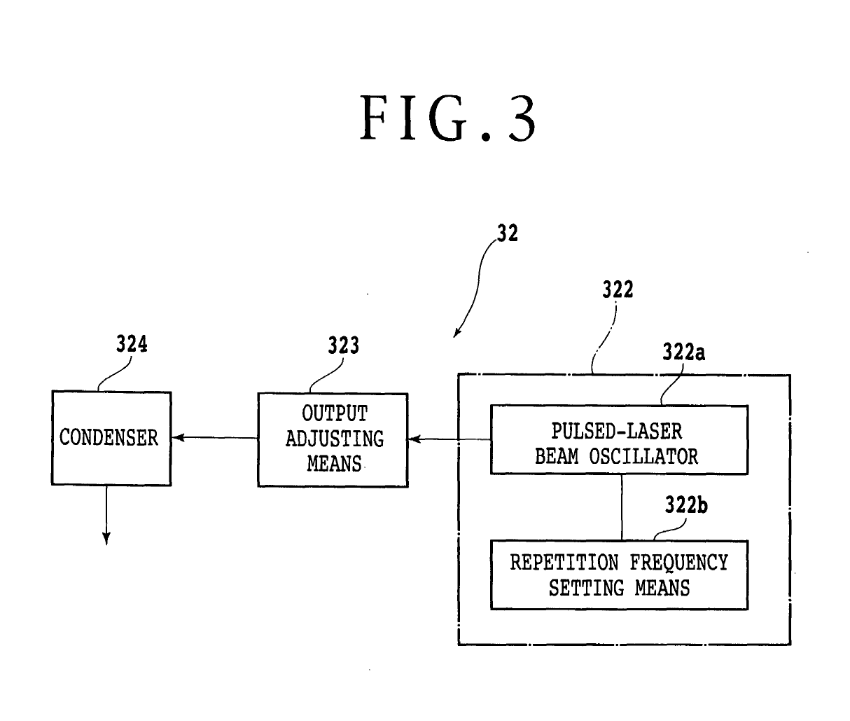

The semiconductor wafer 2 is drilled to define therein via holes reaching the respective bonding pads 24 by radiating a pulsed-laser beam to the silicon substrate 21 from a back surface 21b side of the silicon substrate 21. Here, the process for drilling the silicon substrate 21 of the semiconductor wafer 2 to define therein the via holes is carried out by using laser beam processing apparatus 3 shown in FIGS. 2 and 3. The laser beam processing apparatus 3 shown in FIGS. 2 and 3 includes a chuck table 31 for holding thereon a work piece by suction, and a laser beam radiating means 32 for radiating a pulsed-laser beam to the work piece held on the chuck table 31 by the suction. The chuck table 31 is constructed so as to hold thereon the work piece by the suction. In addition, the chuck table 31 is adapted to be moved in a processing and feeding direction indicated by an arrow X shown in FIG. 2 by a processing and feeding mechanism (not shown), and is adapted to be moved in an indexing direction indicated by an arrow Y in FIG. 2 by an indexing mechanism (not shown).

The laser beam radiating means 32 includes a cylindrical casing 321 which is substantially disposed horizontally. As shown in FIG. 3, a laser beam oscillating means 322 and an output adjusting means 323 are disposed inside the cylindrical casing 321. The pulsed-laser beam oscillating means 322 is composed of a pulsed-laser beam oscillator 322a constituted by either a YAG laser oscillator or a YVO4 laser oscillator, and a repetition frequency setting means 322b disposed adjacent to the pulsed-laser beam oscillator 322a. The output adjusting means 323 adjusts an output of a pulsed-laser beam emitted from the pulsed-laser beam oscillating means 322 to desired one. Both the pulsed-laser beam oscillating means 322 and the output adjusting means 323 are controlled by a control means (not shown). One head portion of the cylindrical casing 321 is equipped with a condenser 324 in which a condenser lens (not shown) composed of paired lenses is accommodated. Here, the paired lenses may be structured in the well-known form in themselves. The pulsed-laser beam emitted from the pulsed-laser beam oscillating means 322 is condensed by the condenser 324 to have a condensed spot diameter, and the pulsed-laser beam thus condensed is radiated to the work piece held on the chuck table 31 by the suction.

As shown in FIG. 2, the laser beam processing apparatus 3 includes an image pick-up means 33. Here, the other head portion of the cylindrical casing 321 constituting the laser beam radiating means 32 is equipped with the image pick-up means 33. The image pickup means 33 is composed of an infrared illuminating means for radiating infrared rays to the work piece, an optical system for capturing the infrared rays radiated from the infrared illuminating means, an image pickup element (infrared CCD) for outputting an electrical signal corresponding to the infrared rays captured by the optical system, in addition to a normal image pickup element (CCD) for capturing an image of an object with a visible light. In addition, the image pickup means 33 sends an image signal obtained through the image capturing to the control means (not shown).

Hereinafter, a detailed description will be given with respect to the wafer processing method of forming a via hole reaching the bonding pad 24 in the silicon substrate 21 of the semiconductor wafer 2 shown in FIG. 1 by using the laser beam processing apparatus 3 shown in FIGS. 2 and 3. Firstly, as shown in FIG. 2, the semiconductor wafer 2 is placed on the chuck table 31 of the laser beam processing apparatus 3 with the surface 21a thereof disposed face-down, and is held on the chuck table 31 by the suction. As a result, the semiconductor wafer 2 is held on the chuck table 31 with a back surface 21b thereof disposed face-up.

The chuck table 31 which holds thereon the semiconductor wafer 2 by the suction in the manner as described above is positioned right under the image pickup means 33 by the processing and feeding mechanism (not shown). When the chuck table 31 is positioned right under the image pickup means 33, the semiconductor wafer 2 held on the chuck table 31 by the suction is positioned in a predetermined position on the X-Y coordinates. In this state, there is carried out an alignment work for judging whether or not the streets 22 formed in matrix on the surface 21a of the semiconductor wafer 2 held on the chuck table 31 by the suction are disposed in parallel with the X direction and the Y direction, respectively. That is to say, the alignment work is carried out in such a way that an image of the semiconductor wafer 2 held on the chuck table 31 is captured by the image pickup means 33, and image processing such as pattern matching is executed. At this time, the surface 21a of the silicon substrate 21 of the semiconductor wafer 2, on which the streets 22 are formed in matrix is disposed face-down. However, an image of the streets 22 can be captured through the back surface 21b of the silicon substrate 21 because the image pickup means 33, as described above, includes the image pickup means composed of the infrared illuminating means, the optical system for capturing the infrared rays, the image pickup element (infrared CCD) for outputting the electrical signal corresponding to the infrared rays, and the like.

The carrying out of the alignment work described above results in that the semiconductor wafer 2 held on the chuck table 31 by the suction is positioned in the predetermined position on the X-Y coordinates. It is noted that the position coordinates in design of a plurality of bonding pads 24 which are formed on each of the devices 23 formed on the surface 21a of the silicon substrate 21 of the semiconductor wafer 2 are stored in the control means (not shown) of the laser beam processing apparatus 3 in advance.

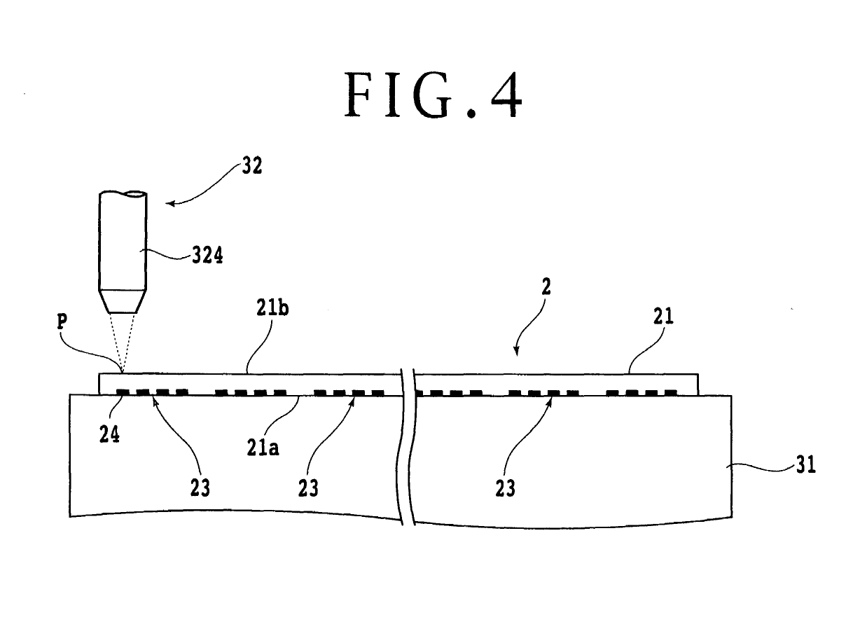

After the alignment work is carried out, the chuck table 31 is moved as shown in FIG. 4, so that the device 23, at the most left-hand end in FIG. 4, of a plurality of devices 23 formed in a predetermined direction on the surface 21a of the silicon substrate 21 of the semiconductor wafer 2 is positioned right under the condenser 324. Next, the bonding pad 24, at the most left-hand end in FIG. 4, of a plurality of bonding pads 24 formed on the device 23 at the most left-hand end in FIG. 4 is positioned just under the condenser 324.

Next, the laser beam illuminating means 32 is activated to carry out a via hole forming process for radiating the pulsed-laser beam to the silicon substrate 21 from the back surface 21b side of the silicon substrate 21 through the condenser 324, thereby forming a via hole reaching the bonding pad 24 from the back surface 21b in the silicon substrate 21. At this time, a condensed spot P of the pulsed-laser beam is focused on the vicinity of the back surface 21b (upper surface) of the silicon substrate 21. Note that, it is preferable that a pulsed-laser beam which has a wavelength of 355 nm and which has an absorptivity to the silicon substrate 21 is used as the pulsed-laser beam to be radiated, and an energy density per one pulse of the pulsed-laser beam is set in the range of 20 to 35 J/cm² with which the silicon substrate 21 is ablation-processed, but none of the bonding pads 24 made of the metal is ablation-processed. That is to say, the energy density of 20 J/cm² per one pulse of the pulsed-laser beam is a lower limit with which the silicon substrate 21 can be ablation-processed. On the other hand, the energy density of 35 J/cm² per one pulse of the pulsed-laser beam is an upper limit with which none of the bonding pads 24 made of the metal is can be ablation-processed.

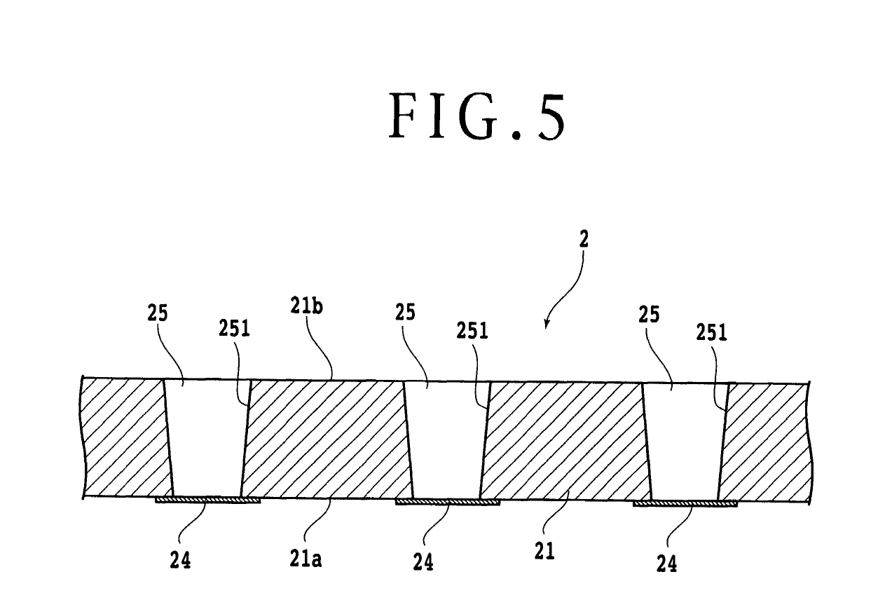

When the pulsed-laser beam having the energy density of 35 J/cm² per one pulse is radiated to the silicon substrate 21 from the back surface 21b of the silicon substrate 21, a hole having a depth of 2 μm can be formed with one pulse of the pulsed-laser beam. Therefore, when a thickness of the silicon substrate 21 is 100 μm, a via hole 25 reaching the surface 21a, that is, the bonding pad 24 from the back surface 21b can be formed in the silicon substrate 21 as shown in FIG. 5 by radiating the pulsed-laser beam to the silicon substrate 21 by 50 pulses. On the other hand, when the pulsed-laser beam having the energy density of 20 J/cm² per one pulse is used, the via hole 25 reaching the surface 21a, that is, the bonding pad 24 from the back surface 21b can be formed in the silicon substrate 21 as shown in FIG. 5 by radiating the pulsed-laser beam to the silicon substrate 21 having the thickness of 100 μm by 80 pulses.

However, even when the energy density per one pulse of the pulsed-laser beam is set in the range of 20 to 35 J/cm² with which the silicon substrate 21 is ablation-processed, but none of the bonding pads 24 made of the metal is ablation-processed, if the thickness of the bonding pad 24 is about 1 μm as with the past, the bonding pad 24 is molten to make a hole in its position by the heat accumulated in a phase of the processing for the silicon substrate 21, and the radiation of the pulsed-laser beam. However, each of the bonding pads 24 in this embodiment shown in the figures, as described above, is made of the metal having the high melting point and the thickness thereof is set as being equal to or larger than 5 μm. As a result, even when the via hole forming process described above is carried out, the bonding pad 24 is prevented from being molten to make a hole in its position.

### Example

In a wafer in which bonding pads made of aluminum having a thickness of 1 μm were formed on a surface of a silicon substrate having a thickness of 100 μm, a gold (Au) film having a thickness of 5 μm was laminated over surfaces of the bonding pads made of aluminum by performing the vacuum evaporation. The above via hole forming process was carried out from a back surface side of the wafer thus formed under the following processing conditions:

Light source of laser beam: YAG laser

Wavelength: 355 nm

Repetition frequency: 10 kHz

Energy density per one pulse: 35 J/cm²

Spot diameter: Φ80 μm

The number of pulses radiated: 50 pulses

As the result of carrying out the via hole forming process under the above processing condition, via holes reaching the respective bonding pads could be formed in the silicon substrate without making any holes in the bonding pads.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A wafer processing method of forming a via hole in a wafer having a surface on which a plurality of devices having bonding pads are formed, said wafer processing method comprising the step of:
forming said via hole reaching said bonding pad by radiating a pulsed-laser beam to said wafer from a back surface side of said wafer;
wherein a thickness of said bonding pad is set as being equal to or larger than 5 μm, a wavelength of the pulsed-laser beam is set to 355 nm, and an energy density per one pulse of the pulsed-laser beam is set in a range of 20 to 35 J/cm².
